(19) United States
(12) Patent Application Publication
(10) Pub. No.: US 2015/0130472 A1
(43) Pub. Date: May 14, 2015

(54) THERMOELECTRIC CONDUCTIVITY MEASUREMENT INSTRUMENT OF THERMOELECTRIC DEVICE AND MEASURING METHOD OF THE SAME

(71) Applicant: Electronics and Telecommunications Research Institute, Daejeon (KR)

(72) Inventors: Dong Suk JUN, Daejeon (KR); Moon Gyu JANG, Daejeon (KR); Won Chul CHOI, Daejeon (KR)

(73) Assignee: Electronics and Telecommunications Research Institute, Daejeon (KR)

(21) Appl. No.: 14/258,732

(22) Filed: Apr. 22, 2014

(30) Foreign Application Priority Data
Nov. 8, 2013 (KR) 10-2013-0135482

(51) Int. Cl. G01N 27/00; G01R 1/02; G01K 13/00; G01R 19/00; G01L 1/00

(52) U.S. Cl. CPC G01N 27/002; G01R 19/00; G01L 1/00; G01K 13/00; G01R 1/02
USPC 324/451

(57) ABSTRACT

Provided are a thermoelectric conductivity measurement instrument of a thermoelectric device and a measuring method of the same. The thermoelectric conductivity measurement instrument of the thermoelectric device includes a sample piece fixing module configured to provide an environment for measuring physical properties of the thermoelectric device as a sample piece and comprising an electrode part configured to provide contact points which are respectively in contact with both ends of the sample piece, and a measuring circuit module configured to provide a source AC voltage of a first frequency heating the sample piece to the electrode part, detect a first thermoelectric AC voltage of a second frequency greater than the first frequency and a second thermoelectric AC voltage of a third frequency greater than the second frequency, which are generated by a temperature change occurring at the contact points, and then obtain the thermoelectric conductivity.

### CROSS-REFERENCE TO RELATED APPLICATIONS

This U.S. non-provisional patent application claims priority under 35 U.S.C. §119 of Korean Patent Application No. 10-2013-0135482, filed on Nov. 8, 2013, the entire contents of which are hereby incorporated by reference.

### BACKGROUND OF THE INVENTION

The present invention disclosed herein relates to a testing apparatus of an electric device and a testing method of the same, and more particularly, to a thermoelectric conductivity measurement instrument of a thermoelectric device and a measuring method of the same.

Recently, due to the growing interest in clean energy, studies have been done on a thermoelectric device has been. The thermoelectric device serves to convert heat energy into electric energy, or reversely to apply the electric energy and generate a difference in temperature.

A 2T value (thermoelectric figure of merit value) is used as an indicator estimating thermoelectric efficiency. A ZT value is in proportion to an electric conductivity and the square of a Seebeck coefficient and in inverse proportion to a thermoelectric conductivity. The 2T value may be decided as a unique property of a corresponding material.

The thermoelectric conductivity may be measured using a contact point between a sample piece and an electrode. A direct current or an alternating current may be applied to the sample piece and the electrode. The contact point between the sample piece and the electrode may be heated by the Peltier effect. The thermoelectric conductivity may be measured according to a temperature change in the contact point. However, it is almost impossible with a current technology to simultaneously measure the thermoelectric conductivity, while heating the contact point.

This is because it is difficult to separate and measure a weak thermoelectric voltage generated at the contact point between a plate electrode and a sample piece from a DC voltage needed to maintain a direct current, when using the direct current. Further, the is also because it is difficult to separate and measure a driving voltage and the thermoelectric voltage, because a frequency of the driving voltage is the same as that of the thermoelectric voltage generated from temperature oscillation induced by the Paltier effect, even when using an alternating current.

### SUMMARY OF THE INVENTION

The present invention provides a thermoelectric conductivity measurement instrument of a thermoelectric device, which can simultaneously measure a thermoelectric conductivity, while changing a temperature of a contact point, and a measuring method of the same.

Embodiments of the inventive concept provide thermoelectric conductivity measurement instruments of a thermoelectric device include a sample piece fixing module configured to provide an environment for measuring physical properties of the thermoelectric device as a sample piece and including an electrode part configured to provide contact points which are respectively in contact with both ends of the sample piece, and a measuring circuit module configured to provide a source AC voltage of a first frequency heating the sample piece to the electrode part, detect a first thermoelectric AC voltage of a second frequency greater than the first frequency and a second thermoelectric AC voltage of a third frequency greater than the second frequency, which are generated by a temperature change occurring at the contact points, and then obtain the thermoelectric conductivity.

In some embodiments, the measuring circuit module may include a low frequency generator configured to generate the source AC voltage and provide the source AC voltage to the electrode part, a first differential amplifier configured to be connected to the electrode part disposed at both ends of the sample piece and amplify the first thermoelectric AC voltage and the second thermoelectric AC voltage, and a lock-in amplifier configured to be connected with the first differential amplifier and the low frequency generator so as to remove a noise and also detect the second thermoelectric AC voltage.

In other embodiments, the measuring circuit module may further include a voltmeter configured to be connected with an input part of the first differential amplifier of the both ends of the sample piece and to measure the first thermoelectric AC voltage.

In still other embodiments, the sample piece fixing module may further include a heater configured to heat the electrode part, the sample piece and the contact points.

In even other embodiments, the measuring circuit module may further include a variable resistor configured to be connected in series between the low frequency generator and the electrode part, a second differential amplifier configured to be connected with the low frequency generator and the electrode part disposed at both ends of the variable resistor, and a comparator configured to be connected to an output part of each of the first and second differential amplifiers and also connected to an input part of the lock-in amplifier.

In yet other embodiments, the instruments may further include 4-point probes configured to be connected to one end of the sample piece and the low frequency generator, connected to the other end of the sample piece and the variable resistor, and connected to the both ends of the sample piece and an input part of the first differential amplifier.

In further embodiments, the lock-in amplifier may include a low-pass filter configured to provide the source AC voltage of the first frequency to the heater.

In still further embodiments, the lock-in amplifier may further include a high-pass filter configured to provide the source AC voltage, in which a noise of a direct current component is removed, to the low-pass filter.

In even further embodiments, the lock-in amplifier may further include a demodulator disposed between the high-pass filter and the low-pass filter.

In yet further embodiments, the sample piece fixing module may include a cryogenic probe station.

In much further embodiments, the electrode part may include a lower electrode disposed under the sample piece and providing one of the contact points, and an upper electrode disposed on the sample piece disposed on the lower electrode and configured to provide the other contact point.

In still much further embodiments, the sample piece fixing module may further include a cooling chuck, a lower support configured to fix the cooling chuck, a medium block disposed on the sample piece and the upper electrode disposed on the cooling chuck and configured to receive the heater, an adiabatic cylinder configured to enclose the medium block and prevent a temperature change in the heater and the medium block, and an upper support configured to fix the adiabatic cylinder to the upper support.

In even much further embodiments, the sample piece fixing module may include a lower temperature sensor disposed between the lower electrode and the cooling chuck and configured to detect a temperature of one of the contact points, and an upper temperature sensor disposed between the upper electrode and the medium block and configured to detect a temperature of the other contact point.

In yet much further embodiments, the instruments may further include a pressure sensor disposed between the upper support and the medium block in the adiabatic cylinder, a piston shaft configured to pass through the upper support and to be connected with the pressure sensor, an air cylinder disposed on the piston shaft and configured to provide a pressure pressing the medium block, the pressure sensor and the piston shaft, and a central support configured to be fixed to the lower support and to fix the air cylinder, the adiabatic cylinder and the upper support.

In other Embodiments of the inventive concept, methods for measuring a thermoelectric conductivity of a thermoelectric device include fixing a sample piece into a sample piece fixing module and providing a contact point between an electrode part and the sample piece in the sample piece fixing module, applying a source AC voltage of a first frequency and locally heating the contact point, measuring first and second thermoelectric AC voltages of second and third frequencies greater than the first frequency from a temperature change due to the heating of the contact point, and calculating the thermoelectric conductivity at the contact point using the first and second thermoelectric AC voltages.

In some embodiments, the heating of the contact point may include heating the electrode part or the sample piece, in turn, and simultaneously measuring a temperature of the electrode part or the sample piece.

In other embodiments, the contact point may have a nano-size.

In still other embodiments, the contact point may be heated by the temperature change of about 2K or less.

### BRIEF DESCRIPTION OF THE DRAWINGS

The accompanying drawings are included to provide a further understanding of the present invention, and are incorporated in and constitute a part of this specification. The drawings illustrate exemplary Embodiments of the inventive concept and, together with the description, serve to explain principles of the present invention. In the drawings:

FIG. 1 is a view schematically illustrating a thermoelectric conductivity measurement instrument of a thermoelectric device in accordance with an embodiment of the inventive concept;

FIGS. 2 and 3 are a perspective view and a side view of a sample piece fixing module;

FIG. 4 is an exploded perspective view of the sample piece fixing module of FIGS. 2 and 3;

FIGS. 5 to 19 are perspective views illustrating a coupling process of each construction element of the sample piece fixing module;

FIG. 20 is a circuit diagram illustrating a measuring circuit module;

FIG. 21 is a circuit diagram specifically illustrating a lock-in amplifier of FIG. 20; and

FIG. 22 is flow chart illustrating a measuring method of the thermoelectric conductivity measurement instrument in accordance with an embodiment of the inventive concept.

### DETAILED DESCRIPTION OF PREFERRED EMBODIMENTS

Preferred Embodiments of the inventive concept will be described below in more detail with reference to the accompanying drawings. These and other advantages and characteristics of the present invention and methods achieving the same appear evident from the following description of preferred embodiments of the invention illustrated, as a non-limiting example, in the figures of the enclosed drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the same components are designated by the same reference numerals over the entire specification.

The terms used herein are merely to describe a specific embodiment, and thus the present invention is not limited to them. Further, as far as singular expression clearly denotes a different meaning in context, it includes plural expression. It is understood that terms “comprises” and/or “comprising” intend to indicate the existence of features, numerals, steps, operations, elements and components described in the specification or the existence of the combination of these, and do not exclude the existence of one or more other features, numerals, steps, operations, elements and components or the existence of the combination of these or additional possibility beforehand. Since exemplary embodiments are provided below, the order of the reference numerals given in the description is not limited thereto.

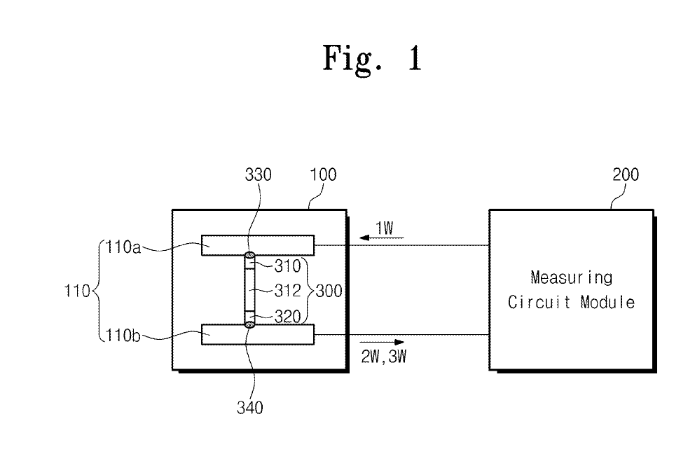

FIG. 1 is a view schematically illustrating a thermoelectric conductivity measurement instrument of a thermoelectric device in accordance with an embodiment of the inventive concept.

Referring to FIG. 1, a thermoelectric device in accordance with an embodiment of the inventive concept may include a sample piece fixing module 100 and a measuring circuit module 200.

The sample piece fixing module 100 may fix a sample piece 300. The sample piece fixing module 100 may include a cryogenic probe station. The sample piece 300 may be disposed at an electrode part 110 of the sample piece fixing module 100. The electrode part 110 may include an upper electrode 110a disposed at an upper side of the sample piece 300 and a lower electrode 110b disposed at a lower side of the sample piece 300.

The sample piece 300 may include a high temperature portion 310, an leg portion 312 and a low temperature portion 320. The high temperature portion 310 may be in contact with the upper electrode 110a. According to one exemplary embodiment, a nano-sized upper contact point 330 may be provided between the high temperature portion and the upper electrode 110a. The low temperature portion 320 may be in contact with the lower electrode 110b. A nano-sized lower contact point 340 may be provided between the low temperature portion and the lower electrode 110b. The leg portion 312 may include a semiconductor layer. For example, the leg portion 312 of the sample piece 300 may include a crystalline silicon layer, a platinum layer on the crystalline silicon layer, and a poly-silicon layer on the platinum layer. The crystalline silicon layer and the poly-silicon layer may be doped with a conductive impurity.

The measuring circuit module 200 may supply a source AC voltage of a first frequency 1w to the electrode part 110 of the sample piece fixing module 100 and the sample piece 300. The sample piece 300 may be self-heated by a source alternating current according to the source AC voltage, and a temperature of the sample piece 300 may be increased. Due to a heated temperature of the sample piece 300, first and second thermoelectric AC voltages of second and third frequencies 2w and 3w which are higher than the first frequency 1w may be generated at the upper contact point 330 or the lower contact point 340 by Seebeck effect. The measuring circuit module 200 may detect the first and second thermoelectric AC voltages of second and third frequencies 2w and 3w and may calculate a thermoelectric conductivity. Therefore, the measuring circuit module 200 may simultaneously detect the first and second thermoelectric AC voltages at the upper contact point 330 or the lower contact point 340 between the sample piece 300 and the electrode part 110, while heating the sample piece 300.

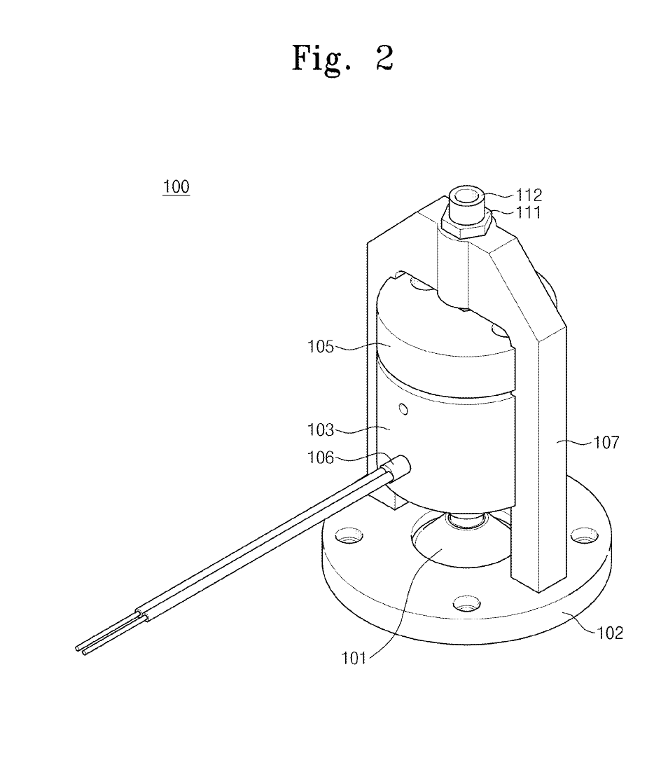

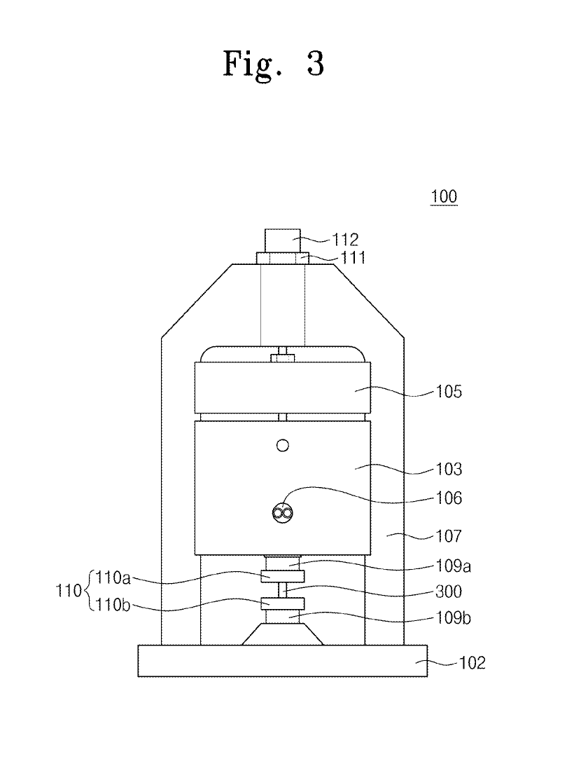

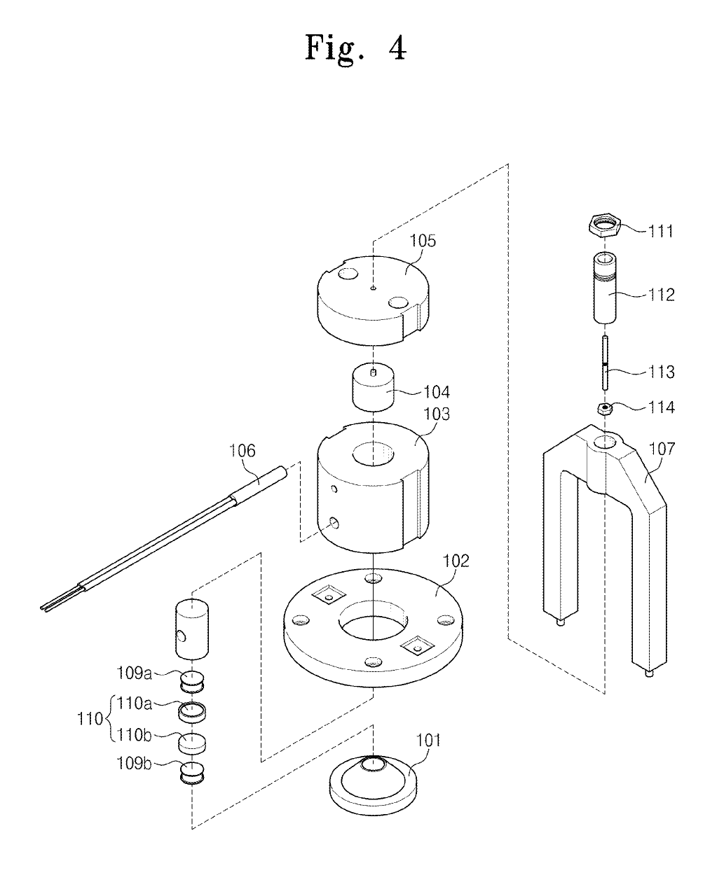

FIGS. 2 and 3 are a perspective view and a side view of the sample piece fixing module 100, and FIG. 4 is an exploded perspective view of the sample piece fixing module of FIGS. 2 and 3.

Referring to FIGS. 2 to 4, the sample piece fixing module 100 may include a cooling chuck 101, a bottom support 102, an adiabatic cylinder 103, a pressure sensor 104, an upper support 105, a heater 106, a central support 107, a medium block 108, upper and lower temperature sensors 109a and 109b, the electrode part 110, a first fixing nut 111, an air cylinder 112, a piston shaft 113 and a second fixing nut 114.

The cooling chuck 101 may be disposed under the lower temperature sensor 109b. The cooling chuck 101 may cool the lower temperature sensor 109b, the lower electrode 110b and the low temperature portion 320 of the sample piece 300.

The bottom support 102 may fix the cooling chuck 101. The bottom support 102 may have a ring shape enclosing the cooling chuck 101.

The lower temperature sensor 109b may be disposed on the cooling chuck 101. The lower temperature sensor 109b may measure a temperature of the low temperature portion 320 of the sample piece 300.

The lower electrode 110b may be disposed on the lower temperature sensor 109b. The low temperature portion 320 of the sample piece 300 may be disposed on the lower electrode 110b. The low temperature portion 320 of the sample piece 300, the lower electrode 110b and the lower temperature sensor 109b may be cooled by the cooling chuck 101. The lower electrode 110b may include a plate electrode.

The upper electrode 110a may be disposed on the high temperature portion 310 of the sample piece 300. The upper electrode 110a may include the plate electrode.

The upper temperature sensor 109a may be disposed on the upper electrode 110a. The upper temperature sensor 109a may measure a temperature of the high temperature portion 310 of the sample piece 300.

The upper electrode 110a and the upper temperature sensor 109a may be disposed, in turn, on the high temperature portion 310 of the sample piece 300. The high temperature portion 310 of the sample piece 300, the upper electrode 110a, the upper temperature sensor 109a and the medium block 108 may be heated by the heater 106.

The heater 106 may passes through a side wall of the adiabatic cylinder 103 and then may be connected with the medium block 108. The heater 106 may generate heat by a source AC voltage of the measuring circuit module 200. The heater 106 may heat the medium block 108 to a first temperature.

The medium block 108 may transfer heat of the first temperature between the heater 106 and the upper temperature sensor 109a.

The adiabatic cylinder 103 may enclose the heater 106, the medium block 108 and the pressure sensor 104. The adiabatic cylinder 103 may preserve the heat of the heater 106. The first temperature in the adiabatic cylinder 103 may be maintained constantly and independently from an external environment. The upper temperature sensor 109a may detect the first temperature of the medium block 108 and the upper electrode 110a.

The upper support 105 may cover the adiabatic cylinder 103 and the pressure sensor 104. The upper support 105 may have the same diameter as that of the adiabatic cylinder 103.

The central support 107 may cover the adiabatic cylinder 103 and the upper support 105. The adiabatic cylinder 103 may be disposed at a center of the central support 107. The central support 107 may be fixed to the bottom support 102.

The air cylinder 112 may pass through the central support 107 and may be supported to the upper support 105. The first fixing nut 111 may fix the air cylinder 112 to the central support 107. An air pressure may be supplied to the air cylinder 112.

The piston shaft 113 may be moved in the air cylinder 112 by the air pressure. The piston shaft 113 may pass through the upper support 105 and may be extended to the pressure sensor 104. The second nut 114 may fix the piston shaft 113 to the upper support 105. The piston shaft 113 may press the upper support 105, the pressure sensor 104, the medium block 108, the upper temperature sensor 109a and the upper electrode 110a toward the high temperature portion 310 of the sample piece 300 with a predetermined pressure.

Therefore, the high temperature portion 310 of the sample piece 300 and the upper electrode 110a may have the upper contact point 330 having a surface area which is in proportion to the air pressure.

A coupling process of the sample piece fixing module 100 is as follows.

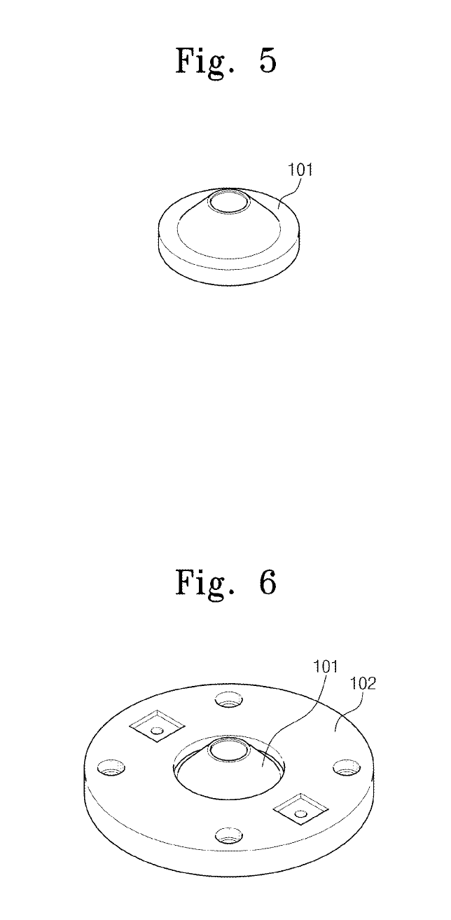

FIGS. 5 to 19 are perspective views illustrating a coupling process of each construction element of the sample piece fixing module 100.

Referring to FIG. 5, the cooling chuck 101 is provided.

Referring to FIG. 6, the bottom support 102 is disposed around an edge of the cooling chuck 101. The cooling chuck 101 may protrude through a center portion of the bottom support 102.

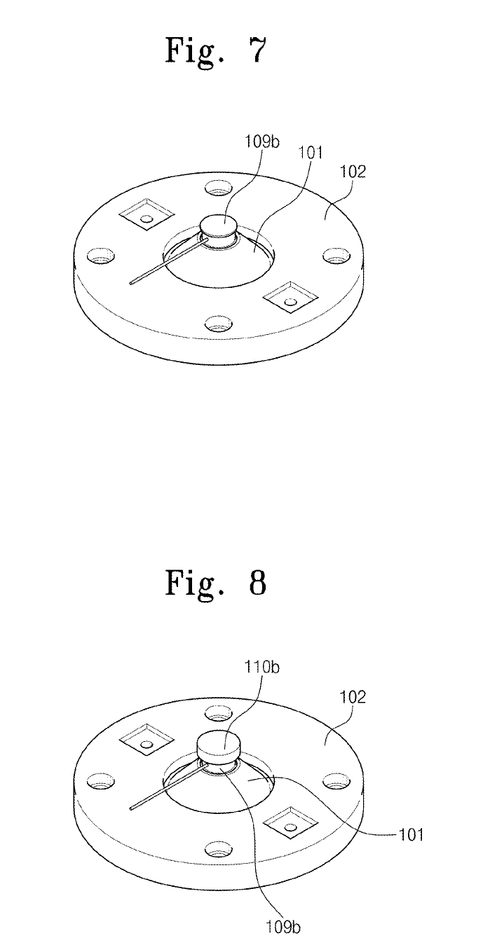

Referring to FIG. 7, the lower temperature sensor 109b is disposed on the cooling chuck 101. The lower temperature sensor 109b may be bonded to the cooling chuck 101 by an adhesive (not shown).

Referring to FIG. 8, the lower electrode 110b is disposed, in turn, on the lower temperature sensor 109b. The lower temperature sensor 109b and the lower electrode 110b may be bonded to each other by the adhesive.

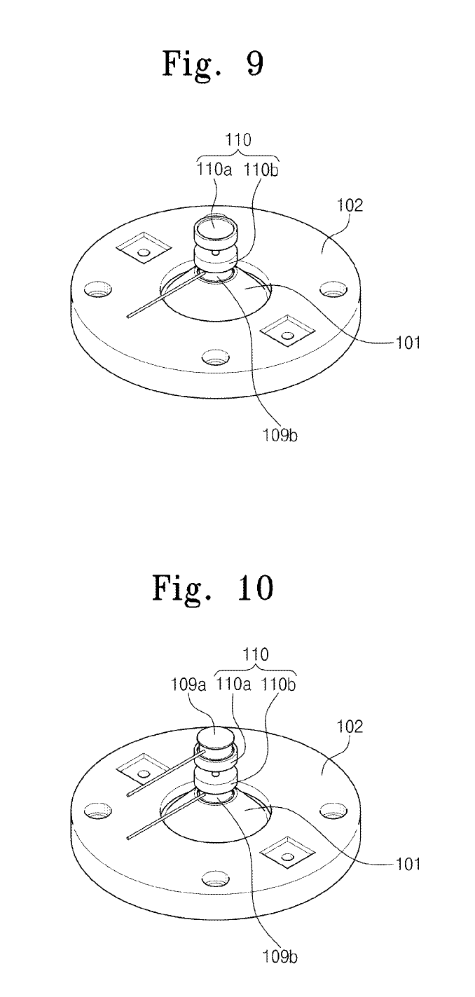

Referring to FIG. 9, the sample piece 300 is mounted on the lower electrode 110b, and the upper electrode 110a is disposed on the sample piece 300. The sample piece 300 and the lower electrode 110b may define the lower contact point 340. The lower temperature sensor 109a may measure a temperature of the lower contact point 340. The sample piece 300 and the upper electrode 110a may define the upper contact point 330.

Referring to FIG. 10, the upper temperature sensor 109a is disposed on the upper electrode 110a. The upper temperature sensor 109a may measure a temperature of the upper contact point 330 between the upper electrode 110a and the sample piece 300.

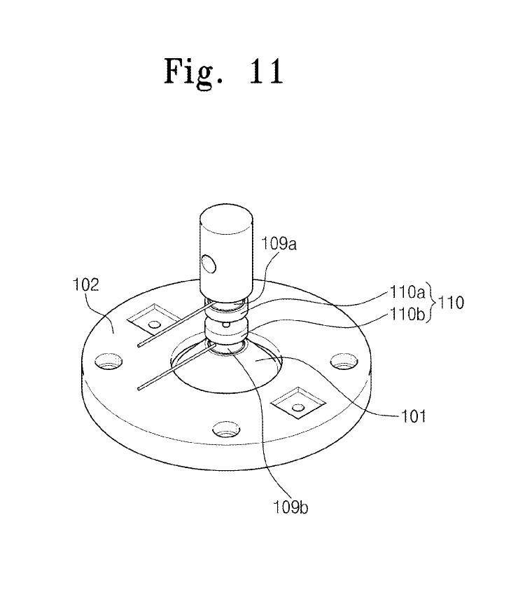

Referring to FIG. 11, the medium block 108 is disposed on the upper temperature sensor 109a.

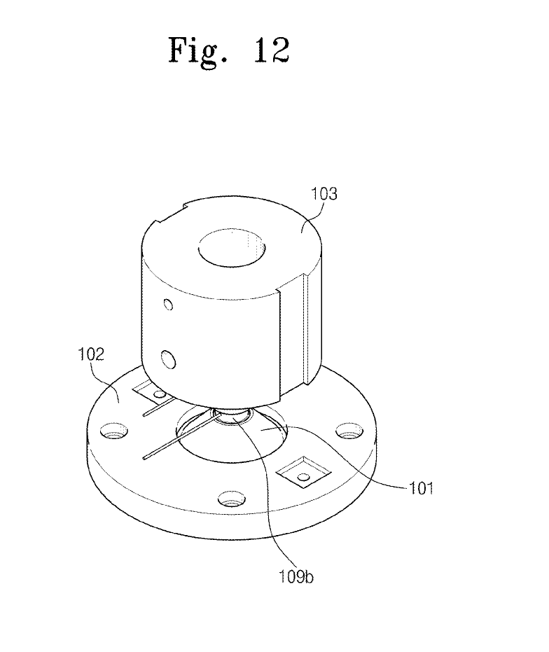

Referring to FIG. 12, the adiabatic cylinder 103 enclosing the medium block 108 is disposed. The adiabatic cylinder 103 may keep the heating of the medium block 108, the upper temperature sensor 109a, the upper electrode 110a and the upper contact point 330.

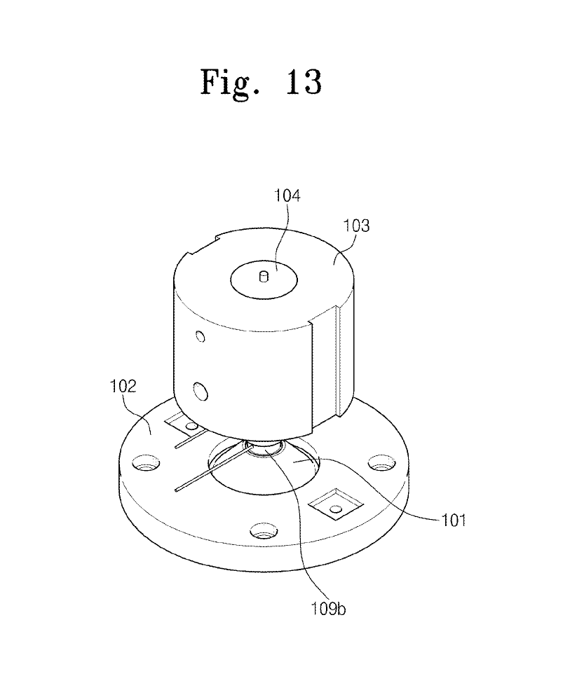

Referring to FIG. 13, the pressure sensor 104 is installed in the adiabatic cylinder 103 on the medium block 108. The pressure sensor 104 may detect a pressure applied to the medium block 108, the upper temperature sensor 209a, the upper electrode 110a and the sample piece 300.

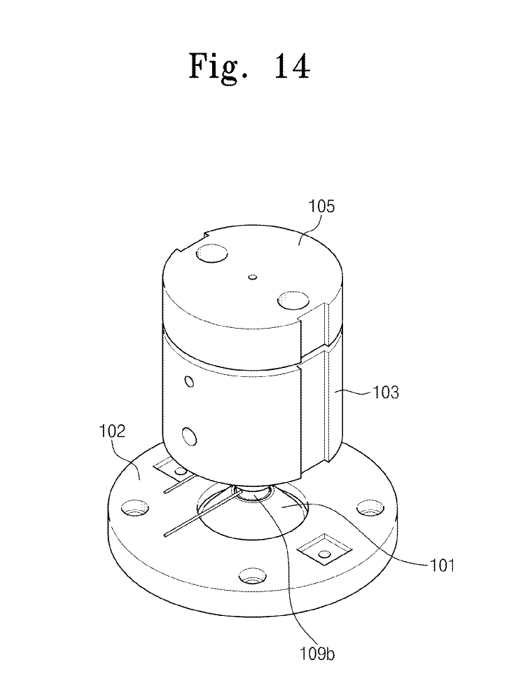

Referring to FIG. 14, the upper support 105 is disposed on the adiabatic cylinder 103 and the pressure sensor 104. The upper support 105 may restrict the pressure sensor 104 and the medium block 108 in the adiabatic cylinder 103. The pressure sensor 104 and the medium block 108 may be moved up and down in the adiabatic cylinder 103.

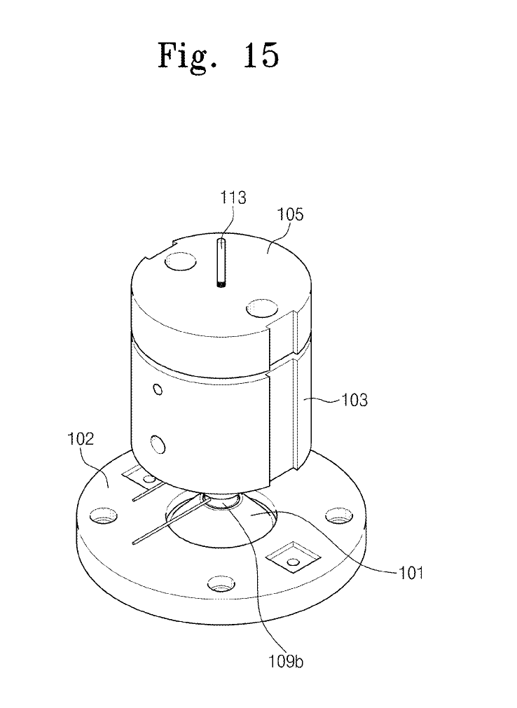

Referring to FIG. 15, the piston shaft 113 is inserted from the upper support 105 into the pressure sensor 104. The piston shaft 113 may press down the pressure sensor 104.

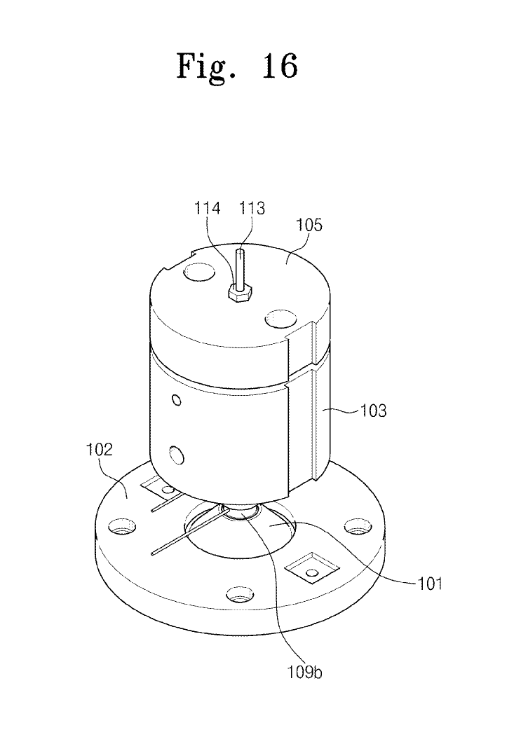

Referring to FIG. 16, the piston shaft 113 is fixed to the upper support 105 by the second nut 114.

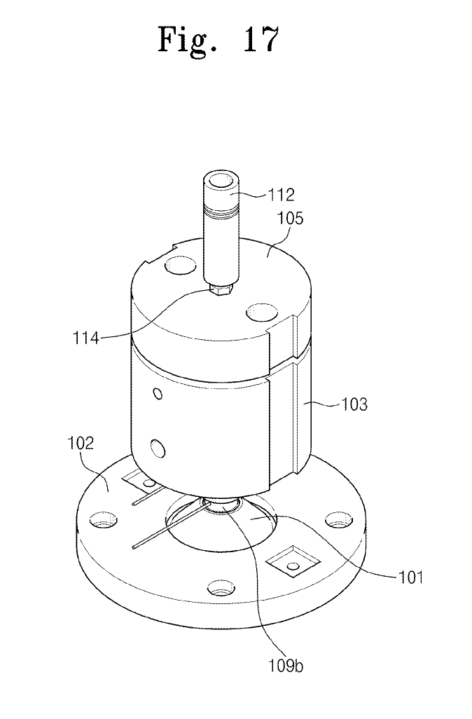

Referring to FIG. 17, the piston shaft 113 is inserted into the air cylinder 112. The air cylinder 112 may provide a pressure to the piston shaft 113 so that the piston shaft 113 may be moved up and down.

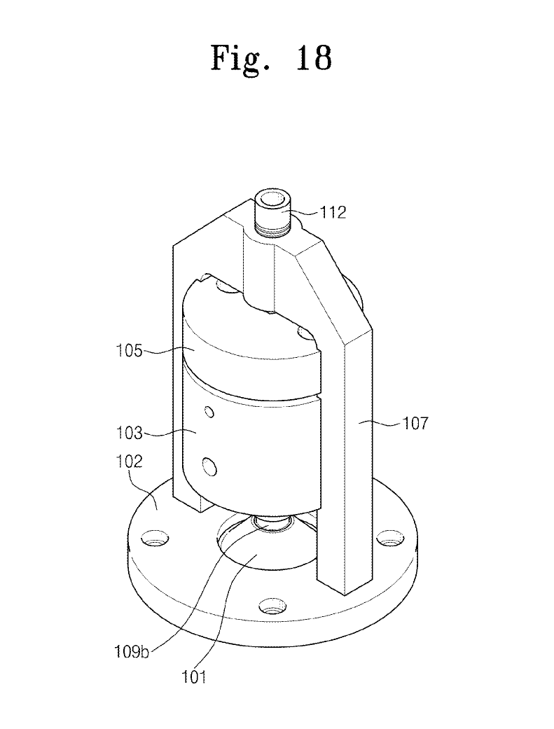

Referring to FIG. 18, the central support 107 is covered on the upper support 105 and the adiabatic cylinder 103. The air cylinder 112 may pass through the central support 107.

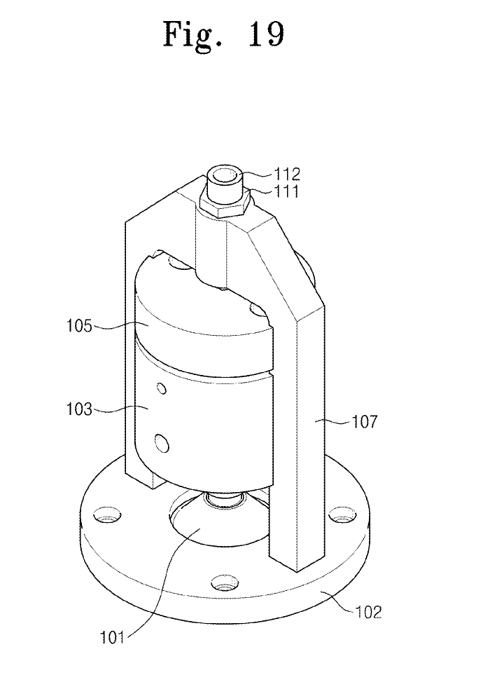

Referring to FIG. 19, the air cylinder 112 may be fixed to the central support 107 by the first fixing nut 111.

Referring to FIG. 2 again, the heater 106 is inserted into the side wall of the adiabatic cylinder 103. The heater 106 may provide heat so as to prevent natural cooling of the sample piece 300. The heater 106 may be heated by the source AC voltage and the source alternating current of the measuring circuit module 200.

Therefore, the sample piece fixing module 100 may provide an environment for measuring the thermoelectric conductivity of the sample piece 300.

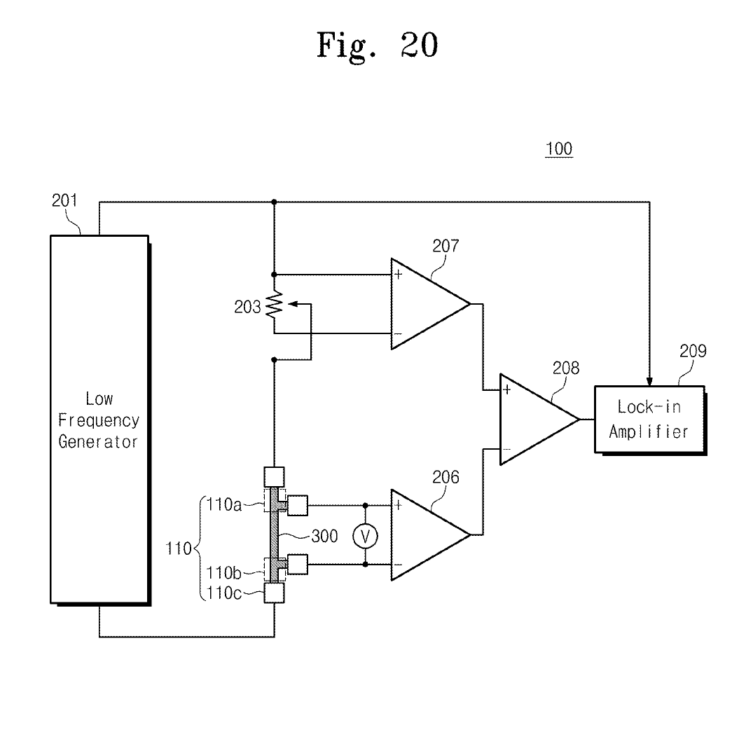

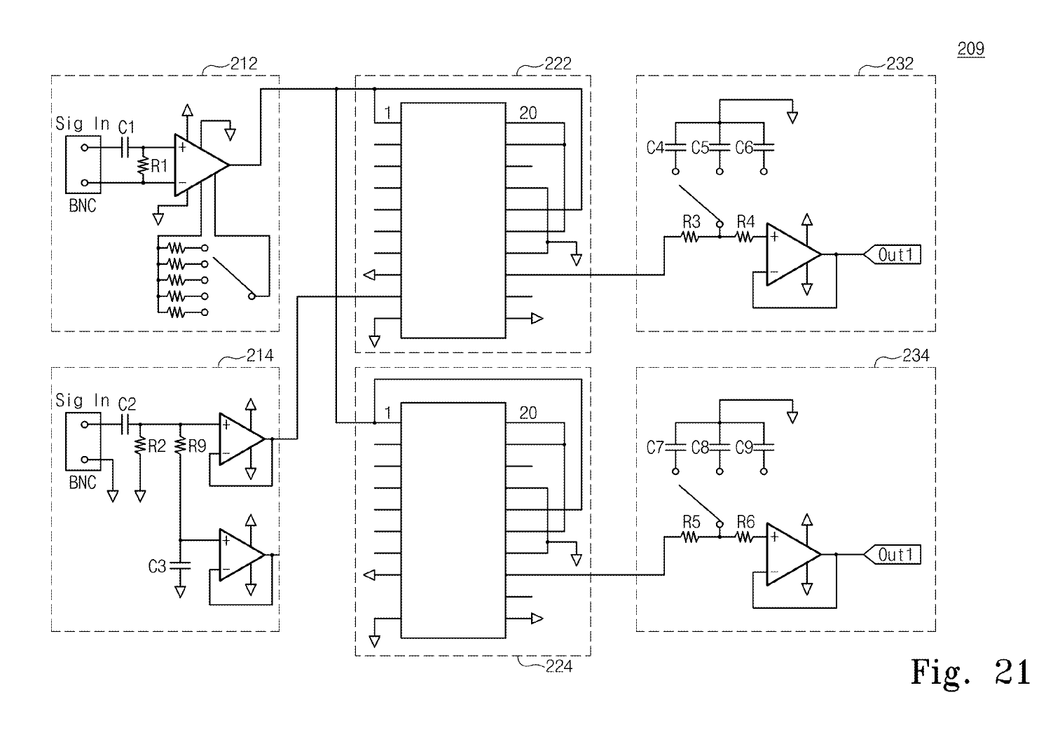

FIG. 20 is a circuit diagram illustrating the measuring circuit module 200.

Referring to FIGS. 1 to 20, the measuring circuit module 200 may include a low frequency generator 201, a variable resistor 203, a voltmeter 205, a first differential amplifier 206, a second differential amplifier 207, a comparator 208 and a lock-in amplifier 209.

The low frequency generator 201 may generate the source AC voltage of the first frequency and then may provide the source AC voltage to the upper electrode 110a and the lower electrode 110b of the electrode part 110. The electrode part 110 may include 4-point probes 110c. The 4-point probes 110c may include a plurality of probe pads connected to the upper and lower electrodes 110a and 110b. For example, in the 4-point probes, part of the plurality of probe pads are connected to the upper electrode 110a, and the rest of them are connected to the lower electrode 110b.

An input part of the first differential amplifier 206 may be connected to each of the upper and lower electrodes 110a and 110b disposed at both ends of the sample piece 300. The first differential amplifier 206 may amplify the first and second thermoelectric AC voltages of the sample piece 300. The first and second thermoelectric AC voltages will be fully described later. An output part of the first differential amplifier 206 may be connected with the comparator 208.

The voltmeter 205 may be connected with each of the high temperature portion 310 and the low temperature portion 320 of the sample piece 300. The voltmeter 205 may measure the first thermoelectric voltage of the second frequency according to a temperature change in the sample piece 300.

The variable resistor 203 may be connected between the low frequency generator 201 and the upper electrode 110a. The variable resistor 203 may be set to have the same resistance value as that of a resistor of the sample piece 300 between the upper electrode 110a and the lower electrode 110b. The variable resistor 203 may have a greater resistance value than that of the resistor of the sample piece 300. The variable resistor 203 may prevent a change in a resistance due to the temperature change at the upper contact point 330 of the upper electrode 110a and the lower contact point 340 of the lower electrode 110b from having an influence on a current flowing in a circuit, and also may constantly maintain the current. The part of the plurality of probe pads of the 4-point probes may be respectively connected with the variable resistor 203 and the low frequency generator 201, and the rest of the plurality of probe pads may be respectively connected with the input part of the first differential amplifier 206.

An input part of the second differential amplifier 207 may be connected with the low frequency generator 201 and the upper electrode 110a disposed at both ends of the variable resistor 203. An output part of the second differential amplifier 207 may be connected with the comparator 208. The second differential amplifier 207 may amplify an AC voltage of the variable resistor 203.

The comparator 208 may be connected with each of the input parts of the first and second differential amplifiers 206 and 207. The comparator 208 may compare the first and second thermoelectric AC voltages of each of the sample piece 300 and the variable resistor 203. An output part of the comparator 208 may be connected with the lock-in amplifier 209.

An input part of the lock-in amplifier 209 may be connected with each of the comparator 208 and the low frequency generator 201. The lock-in amplifier 209 may serve to remove noise from a source AC voltage 106 of the low frequency generator 201, and also to detect the second thermoelectric AC voltage at the first differential amplifier 206.

First of all, the lock-in amplifier 209 may provide the source AC voltage of the first frequency to the heater 106. The noise of second and third frequency components and a direct current component may be removed from the source AC voltage. The removing of the noise from the source AC voltage may be explained through the following Equations 1 to 4.

A reference voltage V_{ref} of the source AC voltage of the first frequency provided from the low frequency generator 201 is expressed as Equation 1

V_{ref}=V_{sig} sin(ωᵣt+θ_{sig}) (Equation 1)

wherein V_{ref} is an input reference voltage, V_{sig} is a signal voltage, ωᵣ is a reference frequency of the first frequency, t is a time variable, and θ_{sig} is a phase of the signal voltage. At this time, the input reference may be the source AC voltage of the first frequency.

An input signal voltage input through the comparator 208 and applied to the lock-in amplifier 209 is expressed as Equation 2.

V_{lock-in}=V_{L} sin(ω_{L}t+θ_{ref}) (Equation 2)

wherein V_{lock-in} is the input signal voltage of the lock-in amplifier 209, V_{L} is a lock-in voltage, ω_{L} is a lock-in frequency, θ_{ref} is a phase of the reference voltage. The input signal voltage may be the first and second thermoelectric AC voltages.

A phase sensitivity detecting voltage of each of the input signal voltage and the input reference voltage in the lock-in amplifier 209 is expressed as Equation 3.

$$\begin{matrix}{V}_{PSD} = {V}_{sig} {V}_{L} sin ( {ω}_{r} t + {ϑ}_{sig} ) sin ( {ω}_{L} t + {ϑ}_{ref} ) \\ = \frac{1}{2} {V}_{sig} {V}_{L} [ \begin{matrix}cos ( [ {ω}_{r} - {ω}_{L} ] + {θ}_{sig} - {θ}_{ref} ) + \\ cos ( [ {ω}_{r} + {ω}_{L} ] t + {ϑ}_{sig} + {ϑ}_{ref} )\end{matrix} ]\end{matrix} \qquad ( Equation 3 )$$

wherein VPSD is the phase sensitivity detecting voltage. A direct current output component of the V_{PSD} may be obtained as Equation 4 under a condition that the reference frequency is the same as the lock-in frequency (ωᵣ=ω_{L}).

$${V}_{PSD} = \frac{1}{2} {V}_{sig} {V}_{L} cos ( {ϑ}_{sig} - {ϑ}_{ref} ) \qquad ( Equation 4 )$$

The lock-in amplifier 209 may detect the phase sensitivity detecting voltage in which the first thermoelectric AC voltage of a 2w component is removed. At this time, the lock-in amplifier 209 may measure an in-phase (x=V_{sig} cos θ), an out-of-phase (r=V_{sig} sin θ), an amplitude (R=\sqrt{X²+Y²}=Vₛᵢₙ), and a phase (θ=tan⁻¹(Y/X)).

FIG. 21 is a circuit diagram specifically illustrating the lock-in amplifier 209 of FIG. 20.

Referring to FIGS. 1 to 21, the lock-in amplifier 209 may include first and second high-pass filters 212 and 214, first and second demodulators 222 and 224, and first and second low-pass filters 232 and 234.

The first and second high-pass filters 212 and 214 may remove the direct current component in each of the input signal voltage and the input reference voltage of the lock-in amplifier 209. Each of the first and second high-pass filters 212 and 214 may be embodied into a C-R circuit. For example, each of the first and second high-pass filters 212 and 214 may include a filter circuit of a first capacitor C1-a first resistor R1 and a filter circuit of a second capacitor C2-a second resistor R2.

The first and second demodulators 222 and 224 may be respectively connected with the first and second high-pass filters 212 and 214. The first and second demodulators 222 and 224 may demodulate the source AC voltage from the input signal voltage and the input reference voltage. The source AC voltage may have only the first to third frequency components with the direct current component being removed.

The first and second low-pass filters 232 and 234 may be respectively connected with the first and second demodulators 222 and 224. The first and second low-pass filters 232 and 234 may remove the second and third frequency components. Each of the first and second low-pass filters 232 and 234 may be embodied into an R-C circuit. For example, each of the first and second low-pass filters 232 and 234 may include a filter circuit of third and fourth resistors R3 and R4-fourth to sixth capacitors C4, C5 and C6, and a filter circuit of fifth and sixth resistors R5 and R6-seventh to ninth capacitors C7, C8 and C9. The source AC voltage transferred through the first and second low-pass filters 232 and 234 may be provided to the heater 106. Therefore, the lock-in amplifier 209 may provide the source AC voltage of the first frequency, in which the noise component is removed, to the heater 106.

Also, the lock-in amplifier 209 may detect the second thermoelectric AC voltage.

Referring to FIGS. 1, 20 and 21, the lock-in amplifier 209 may remove the direct current component and the first frequency component from the input signal voltage passing through the first and second high-pass filters 212 and 214 of the lock-in amplifier 209. This is because the direct current component and the first frequency component are smaller than the second frequency component and the third frequency component.

The source AC voltage provided to the heater 106 or the sample piece 300 is expressed as Equation 5.

I_{h,0}(t)=I_{h,0} cos(ωt) (Equation 5)

wherein I_{h,0}(t) is a source alternating current value, I_{h,0} is an amplitude of the source alternating current, and ω is the first frequency. The source alternating current may generate Joule heating of the sample piece 300. Power using the Joule heating is expressed as Equation 6.

$$\begin{matrix}{P}_{h} ( t ) = {I}_{h , o}^{2} {R}_{h , o} {cos}^{2} ( ω t ) \\ = \frac{1}{2} {I}_{h , o}^{2} {R}_{h , o} ( 1 + cos ( 2 ω t ) )\end{matrix} \qquad ( Equation 6 )$$

wherein Ph(t) is a heating power value, and R_{h,0} is a heating resistance. The first frequency component which is expressed as the square of the source alternating current may be converted into the second frequency component which is greater than the first frequency.

The heating power may be classified into power of the direct current component and power of the second frequency component in Equations 7 and 8.

$${P}_{DC} = \frac{1}{2} {I}_{h , o}^{2} {R}_{h , o} = \frac{1}{2} {P}_{h , o} \qquad ( Equation 7 )$$

wherein P_{DC} is a power value of the direct current component.

$${P}_{AC} = \frac{1}{2} {I}_{h , o}^{2} {R}_{h , o} cos ( 2 ω t ) \qquad ( Equation 8 )$$

wherein P_{AC} is a power value of the alternating current component.

Meanwhile, an average heating power Pᵣₘₛ is expressed as the following Equation 9. The average power value may be the same as the power value of the direct current component.

Pᵣₘₛ=I_{h,rms}²R_{h,0}=P_{DC} (Equation 9)

wherein Pᵣₘₛ is the average power value, and I_{h·rms} is an average heating current value. The average heating current value is expressed as Equation 10.

$$\begin{matrix}{I}_{h \cdot r ms} = \sqrt{\begin{matrix}1 \\ τ\end{matrix} {\int }_{0}^{t} {I}_{h , o}^{2} ( t ) d t} \\ = {I}_{h , o} \sqrt{\begin{matrix}ω \\ 2 π\end{matrix} {\int }_{0}^{\frac{2 n}{ω}} {cos}^{2} ( ω t ) d t} \\ = \frac{{I}_{h , o}}{\sqrt{2}}\end{matrix} \qquad ( Expression 10 )$$

wherein τ is a time required during one cycle of the source alternating current. The τ is a reciprocal number of the first frequency and thus may be indicated by the first frequency. The average heating current value may be in proportion to the amplitude I_{h,0}.

Meanwhile, when the temperature of the heater 106 and the sample piece 300 is changed, the heating power may be generated. The temperature change may be expressed as Equation 11.

ΔT=ΔT_{DC}+|ΔT_{AC}|cos(2ωt+φ) (Equation 11)

wherein ΔT is a temperature changing value, ΔT_{DC} is a temperature changing value of the direct current component, and ΔT_{AC} is a temperature changing value of the alternating current component. The heating resistance is expressed as Equation 12.

Rₕ(t)=R_{h,0}(1+βₕΔT_{DC})+βₕ|T_{AC}|cos(2ωt+φ) (Equation 12)

wherein Rₕ(t) is a heating resistance value, R_{h,0} is an amplitude of the heating resistance value, and βₕ is a temperature coefficient. When the heater resistance of both ends of the sample piece 300 is measured, a heat drop may be detected.

$${V}_{h} ( t ) = {I}_{h , o} {R}_{h , o} [ \begin{matrix}( 1 + {β}_{h} Δ {T}_{DC} ) cos ( ω t ) + \\ \frac{1}{2} {β}_{h} \vert Δ {T}_{AC} \vert cos ( ω t + ϕ ) + \\ \frac{1}{2} {β}_{h} \vert Δ {T}_{AC} \vert cos ( 3 ω t + ϕ )\end{matrix} ] \qquad ( Equation 13 )$$

wherein Vₕ(t) is a Harmony voltage value. The Harmony voltage value may include a second thermoelectric AC voltage value V_{h,3ω}(t) of a thermoelectric conductivity. The second thermoelectric AC voltage value is expressed as Equation 14.

$${V}_{h , 3 ω} ( t ) = \frac{1}{2} {V}_{h , o} {β}_{h} Δ {T}_{AC} \qquad ( Equation 14 )$$

V_{h,3ω}(t) is the second thermoelectric AC voltage value. A magnitude of the second thermoelectric AC voltage value may include useful information such as information about thermoelectricity of the sample piece 300. If the second thermoelectric AC voltage is measured, the temperature coefficient Ph may be calculated. The temperature coefficient may be in proportion to the thermoelectric conductivity. If the second thermoelectric AC voltage value of the third frequency is detected, the thermoelectric conductivity may be calculated, and may be converted into the power of the second thermoelectric AC voltage value. The power may correspond to a heat flow per unit time and unit area, which passes through the upper contact point 330 and the lower contact point 340. The thermoelectric conductivity may correspond to a value obtained by dividing the heat flow by the temperature change. Therefore, the lock-in amplifier 209 may measure the second thermoelectric AC voltage value of the third frequency component.

Equations 15 and 16 indicate the second thermoelectric AC voltage and the temperature change of the alternating current component.

V_{h,3ω}=V_{h,3ω,x}+tV_{h,3ωy} (Equation 15)

ΔT_{AC}=ΔT_{AC,x}+|ΔT_{AC,y} (Equation 16)

Further, the second thermoelectric AC voltage and the temperature change of the alternating current component are complex numbers including the in-phase and the out-of-phase.

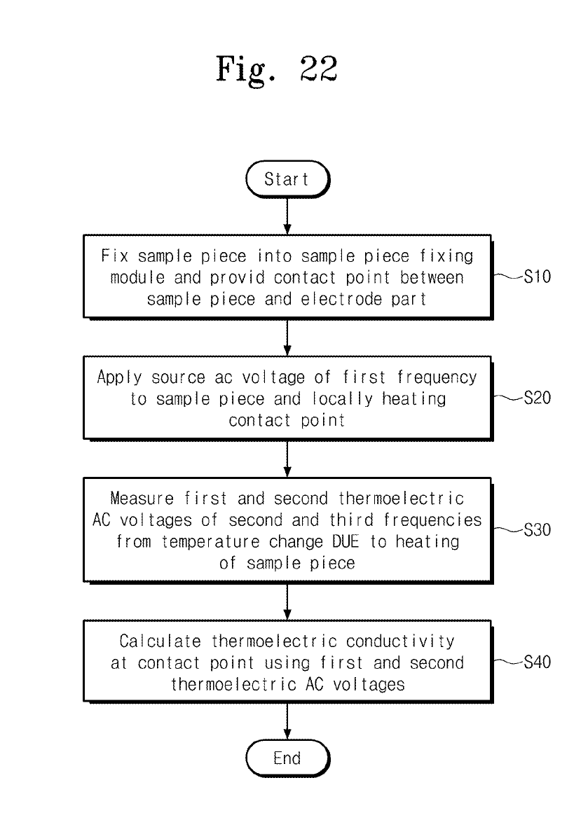

FIG. 22 is flow chart illustrating a measuring method of the thermoelectric conductivity measurement instrument in accordance with an embodiment of the inventive concept.

Referring to FIG. 22, the sample piece 300 is fixed in the sample piece fixing module 100, and the upper contact point 330 is provided between the high temperature portion 310 of the sample piece 300 and the upper electrode 110a, and the lower contact point 340 is provided between the low temperature portion 320 and the lower electrode 110b (S10). Each of the upper and lower contact points 330 and 340 may have a nano-size. The size of the upper contact point 330 may be decided by a pressure between the upper electrode 110a and the high temperature portion 310. The size of the lower contact point 340 may be decided by a pressure between the lower electrode 110b and the low temperature portion 320. A pressure between the upper and lower electrodes 110a and 110b may be detected by the pressure sensor 104.

Then, the source AC voltage is applied to the sample piece 300 so that the upper and lower contact points 330 and 340 are locally heated by the Peltier effect (S20). The upper and lower temperature sensors 109a and 109b may measure the temperature of the upper and lower electrodes 110a and 110b, respectively. In the early stage, the upper and lower electrodes 110a and 110b may be set to the same temperature and thus may have an equilibrium temperature. The upper and lower contact points 330 and 340 may be heated, in turn, in proportion to the source alternating current of the source AC voltage. The source AC voltage and the source alternating current may have the first frequency. The upper and lower electrodes 110a and 110b may be heated by the temperature change within a range of about 2K (degree k).

Then, each of the first thermoelectric AC voltage and the second thermoelectric AC voltage is measured from the temperature change due to the heating of the upper and lower contact points 330 and 340 (S30). If the source AC voltage is removed by the lock-in amplifier 209, the first thermoelectric AC voltage and the second thermoelectric AC voltage may be measured. As described above, the first thermoelectric AC voltage and the second thermoelectric AC voltage may respectively have the second frequency and the third frequency which are greater than the first frequency.

And the thermoelectric conductivity may be calculated at each of the upper and lower contact points 330 and 340 using the first thermoelectric AC voltage and the second thermoelectric AC voltage (S40). The second thermoelectric AC voltage which is the Harmony voltage may be proportional to the thermoelectric conductivity corresponding to the temperature coefficient. The thermoelectric conductivity may correspond to a value obtained by dividing the second thermoelectric AC voltage by the temperature change.

Finally, the thermoelectric conductivity may be calculated at each of the upper and lower contact points 330 and 340 between the sample piece 300 and the electrode part 110 using the second thermoelectric AC voltage and the third thermoelectric AC voltage. The thermoelectric conductivity may be defined as the value obtained by dividing the heat flow per unit time and unit area by the temperature change. The heat flow may correspond to the power applied to the sample piece 300. As described above, the power may correspond to the product of a specific resistance of the sample piece 300 and one of the second thermoelectric AC voltage and the third thermoelectric AC voltage. The temperature change may be 2K.

Therefore, the measuring method of the thermoelectric conductivity according to the exemplary embodiment of the inventive concept may calculate the thermoelectric conductivity, while changing the temperature of the sample piece.

As described above, the thermoelectric conductivity measurement instrument of the thermoelectric device according to the exemplary Embodiments of the inventive concept may include the device fixing module having the electrodes connected with the thermoelectric device and the heater heating the thermoelectric device, and the measuring circuit module configured to provide the source alternating current to the thermoelectric device through the electrodes and to measure the thermoelectric AC voltage. The device fixing module and the measuring circuit module may simultaneously detect the thermoelectric AC voltage according to the temperature change of the contact point, while heating the contact point between the electrodes and the thermoelectric device. The thermoelectric AC voltage may be calculated as the thermoelectric conductivity according to the temperature change of the contact point. Therefore, the thermoelectric conductivity measurement instrument of the thermoelectric device according to the exemplary Embodiments of the inventive concept may calculate the thermoelectric conductivity.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A thermoelectric conductivity measurement instrument of a thermoelectric device, comprising:
a sample piece fixing module configured to provide an environment for measuring physical properties of the thermoelectric device as a sample piece and comprising an electrode part configured to provide contact points which are respectively in contact with both ends of the sample piece; and
a measuring circuit module configured to provide a source AC voltage of a first frequency heating the sample piece to the electrode part, detect a first thermoelectric AC voltage of a second frequency greater than the first frequency and a second thermoelectric AC voltage of a third frequency greater than the second frequency, which are generated by a temperature change occurring at the contact points, and then obtain the thermoelectric conductivity.

2. The instrument of claim 1, wherein the measuring circuit module comprises,
a low frequency generator configured to generate the source AC voltage and provide the source AC voltage to the electrode part;
a first differential amplifier configured to be connected to the electrode part disposed at both ends of the sample piece and amplify the first thermoelectric AC voltage and the second thermoelectric AC voltage; and
a lock-in amplifier configured to be connected with the first differential amplifier and the low frequency generator so as to remove a noise and also detect the second thermoelectric AC voltage.

3. The instrument of claim 2, wherein the measuring circuit module further comprises a voltmeter configured to be connected with an input part of the first differential amplifier of the both ends of the sample piece and to measure the first thermoelectric AC voltage.

4. The instrument of claim 2, wherein the sample piece fixing module further comprises a heater configured to heat the electrode part, the sample piece and the contact points.

5. The instrument of claim 4, wherein the measuring circuit module further comprises,
a variable resistor configured to be connected in series between the low frequency generator and the electrode part;
a second differential amplifier configured to be connected with the low frequency generator and the electrode part disposed at both ends of the variable resistor; and
a comparator configured to be connected to an output part of each of the first and second differential amplifiers and also connected to an input part of the lock-in amplifier.

6. The instrument of claim 5, further comprising 4-point probes configured to be connected to one end of the sample piece and the low frequency generator, connected to the other end of the sample piece and the variable resistor, and connected to the both ends of the sample piece and an input part of the first differential amplifier.

7. The instrument of claim 5, wherein the lock-in amplifier comprises a low-pass filter configured to provide the source AC voltage of the first frequency to the heater.

8. The instrument of claim 7, wherein the lock-in amplifier further comprises a high-pass filter configured to provide the source AC voltage, in which a noise of a direct current component is removed, to the low-pass filter.

9. The instrument of claim 8, wherein the lock-in amplifier further comprises a demodulator disposed between the high-pass filter and the low-pass filter.

10. The instrument of claim 4, wherein the sample piece fixing module comprises a cryogenic probe station.

11. The instrument of claim 4, wherein the electrode part comprises, a lower electrode disposed under the sample piece and providing one of the contact points; and
an upper electrode disposed on the sample piece disposed on the lower electrode and configured to provide the other contact point.

12. The instrument of claim 11, wherein the sample piece fixing module further comprises,
a cooling chuck;
a lower support configured to fix the cooling chuck;
a medium block disposed on the sample piece and the upper electrode disposed on the cooling chuck and configured to receive the heater;
an adiabatic cylinder configured to enclose the medium block and prevent a temperature change in the heater and the medium block; and
an upper support configured to fix the adiabatic cylinder to the upper support.

13. The instrument of claim 12, wherein the sample piece fixing module further comprise,
a lower temperature sensor disposed between the lower electrode and the cooling chuck and configured to detect a temperature of one of the contact points; and
an upper temperature sensor disposed between the upper electrode and the medium block and configured to detect a temperature of the other contact point.

14. The instrument of claim 11, further comprising
a pressure sensor disposed between the upper support and the medium block in the adiabatic cylinder;
a piston shaft configured to pass through the upper support and to be connected with the pressure sensor;
an air cylinder disposed on the piston shaft and configured to provide a pressure pressing the medium block, the pressure sensor and the piston shaft; and
a central support configured to be fixed to the lower support and to fix the air cylinder, the adiabatic cylinder and the upper support.

15. A method for measuring a thermoelectric conductivity of a thermoelectric device, comprising:
fixing a sample piece into a sample piece fixing module and providing a contact point between an electrode part and the sample piece in the sample piece fixing module;
applying a source AC voltage of a first frequency and locally heating the contact point;
measuring first and second thermoelectric AC voltages of second and third frequencies greater than the first frequency from a temperature change due to the heating of the contact point; and
calculating the thermoelectric conductivity at the contact point using the first and second thermoelectric AC voltages.

16. The method of claim 15, wherein the heating of the contact point comprises heating the electrode part or the sample piece, in turn, and simultaneously measuring a temperature of the electrode part or the sample piece.

17. The method of claim 15, wherein the contact point has a nano-size.

18. The method of claim 15, wherein the contact point is heated by the temperature change of about 2K or less.
